(19) United States
(12) Patent Application Publication
(10) Pub. No.: US 2007/0137836 A1
(43) Pub. Date: Jun. 21, 2007

(54) Heat transfer system

(75) Inventor: Brian A. Hamman, Krugerville, TX (US)

Correspondence Address: Arthur W. Fisher;Patent Dominion Partnership, LP, 6103 Twin Oaks Circle, Dallas, TX, 75240, US

(73) Assignee: QNX Cooling Systems, Inc.

(21) Appl. No.: 11/303,623

(22) Filed: Dec. 19, 2005

(51) Int. Cl. H05K 7/20

(52) U.S. Cl. 165/80.4; 361/699

(57) ABSTRACT

Heat transfer systems and thermal pastes for use with cooling systems for cooling heat generating components with hot spots are presented. A number of embodiments are presented. The heat transfer unit has a housing with one surface open or partially open. A plurality of small heat conducting materials are thermally coupled to known hot spots of the heat generating components. Coolant flowing through the housing, comes into direct contact with the small areas of heat conducting materials and the surface of the heat generating component, absorbing heat from the components and cooling them. A thermal paste comprising a mixture of finely powdered crystalline carbon and an adhesive couples heat transfer units to the heat generating components. Heat transfer systems and heat spreaders using crystalline carbon are also presented.

### CROSS REFERENCE TO RELATED APPLICATIONS

Reference is made to pending U.S. patent application Ser. No. 10/688,587 filed Oct. 18, 2003 for a detailed description of a cooling systems and various heat transfer units and heat exchangers and their operation.

### BACKGROUND OF THE INVENTION

### Description of the Related Art

At the heart of data processing and telecommunication devices are processors and other heat-generating components which are becoming increasingly more powerful and generating increasing amounts of heat. As a result, more powerful cooling systems are required to prevent these components from thermal overload and resulting system malfunctions or slowdowns.

Traditional cooling approaches such as heat sinks and heat pipes are unable to practically keep up with this growing heat problem. Cooling systems which use a liquid or gas to cool these heat generating components are becoming increasingly more needed and viable. These systems utilize heat transfer units thermally coupled to the heat generating components for absorbing or extracting heat from the heat generating components into a coolant flowing there through. The coolant, now heated is directed to a heat exchanger where heat is dissipated from the coolant, creating cooled coolant and return to the heat transfer unit to repeat the cycle.

Most heat generating components have “hot spots” where, as necessitated by the design of the component, concentrations of heat will build up. These “hot spots” can be accurately predicted from the design. Many chip manufacturers have used thermal spreaders to more evenly distribute the heat over the surface of the chip. They have also employed the use of thermal throttling circuitry which senses the internal chip temperature and slows down or even shuts down the operation of the chip when a certain temperature is reached. This has become a virtually necessity when heat sinks or heat pipes are used.

Liquid cooling for these heat generating components is a much viable approach to this heat problem. A typical liquid cooling system employs one or more heat transfer units thermally coupled to the heat generating components for absorbing heat from the components into the liquid coolant and a heat exchanger which dissipates heat from the coolant and returns cooled liquid to the heat transfer units.

The heat transfer unit is typically comprised of a housing with a cavity there through for the coolant to flow through. The contact surface (with the heat generating components) is preferably thin and has excellent thermal transfer capability, such as copper. However, any material chosen for the contact surface will add thermal resistance to the transfer of heat from the components to the coolant and impact the thermal performance. Consequently it is desirable for many applications to eliminate the surface all together and let coolant come into direct contact with the component. This is referred to as direct exposure cooling.

If a thermal spreader is used, it helps to spread the heat across the entire surface of the component providing a larger area for cooling/heat absorption. However, it too adds thermal resistance to the cooling system impairing its optimal thermal performance. If no thermal spreader is used, direct contact with the chip packaging by the coolant can occur, but the concentrations of heat at the “hot spots” makes the thermal transfer to the coolant less than optimal because of the more limited area of contact between the “hot spot” and the coolant.

Most heat transfer units, whether liquid cooling, heat sink, heat pipe, etc. use a thermal compound which provides a more uniform thermal coupling between the heat transfer and the heat generating component with excellent thermal transfer capability so as to minimize thermal resistance. For direct exposure heat transfer units, the compound must also provide good sealing qualities so that none of the coolant will leak or spill. As the heat generating components become more and more powerful, the thermal transfer capability of the compound becomes more and more important.

Thus, there is a need in the art for a method and apparatus for more achieving optimal direct and indirect exposure cooling of powerful heat generating components such as today's microprocessors.

There is also a need in the art for a thermal paste or compound having optimal thermal transfer capability.

There is also a need in the art for more efficient means of spreading and transferring heat generated by powerful heat generating components.

### SUMMARY OF THE INVENTION

A method and apparatus for cooling heat generating components having heat transfer units with a housing coupled to one or more heat generating components with at least one surface open or partially open and a plurality of small areas of heat conducting material thermally coupled to known hot spots of the heat generating components such that coolant flowing through the housing comes into direct or indirect contact with the small areas and with the heat generating components.

A method and apparatus for connecting the small areas of heat conducting material to the housing.

A method and apparatus for thermally coupling the small areas of heat conducting material to the hot spots of the heat generating components before the housing is coupled to the heat generating components.

A method and apparatus for positioning an inlet for cooled coolant to the heat transfer unit below and outlet for heated coolant from the heat transfer unit for enhancing convective circulation of the coolant.

A method and apparatus for cooling heat generating components having a heat exchange unit for receiving heated coolant from the heat transfer units, dissipating heat from the coolant creating cooled coolant and directing the cooled coolant to the heat transfer units.

A system having one or more processors and one or more heat transfer units with a housing coupled to one or more heat generating components with at least one surface open or partially open and a plurality of small areas of heat conducting material thermally coupled to known hot spots of the heat generating components such that coolant flowing through the housing comes into direct or indirect contact with the small areas and with the heat generating components.

An optical device having a heat transfer unit with a housing coupled to one or more heat generating components with at least one surface open or partially open and a plurality of small areas of heat conducting material thermally coupled to known hot spots of the heat generating components such that coolant flowing through the housing comes into direct contact with the small areas and with the heat generating components.

A compound having finely powdered crystalline carbon for thermally coupling components together.

A compound having finely powdered crystalline carbon for thermally coupling components together and having a substance for providing paste-like quality and enhancing the thermal coupling of the components.

A compound having finely powdered crystalline carbon for thermally coupling components together and having a substance for providing paste-like quality and enhancing the thermal coupling of the components and having an adhesive substance for securing the components together.

A system having one or more processors and utilizing a finely powdered crystalline carbon compound for thermally coupling components.

An optical device utilizing a finely powdered crystalline carbon compound for thermally coupling components.

A cooling system having one or more heat transfer units with a housing thermally coupled to one or more heat generating components, one more cavities in the housing with a coolant flowing there through for absorbing heat from the heat generating components and a heat transfer means of crystalline carbon for transfer heat from the heat generating components to the cavities.

A cooling system having one or more heat transfer units with a housing thermally coupled to one or more heat generating components, one more cavities in the housing with a coolant flowing there through for absorbing heat from the heat generating components and a heat transfer means of crystalline carbon for transfer heat from the heat generating components to the cavities and where the heat transfer means is embedded in the packaging of the heat generating component.

A cooling system having one or more heat transfer units with a housing thermally coupled to one or more heat generating components, one more cavities in the housing with a coolant flowing there through for absorbing heat from the heat generating components and a heat transfer means of crystalline carbon for transfer heat from the heat generating components to the cavities and where the heat transfer means is embedded in the substrate of the heat generating component.

A cooling system having one or more heat transfer units with a housing thermally coupled to one or more heat generating components, one more cavities in the housing with a coolant flowing there through for absorbing heat from the heat generating components and a heat transfer means of crystalline carbon for transfer heat from the heat generating components to the cavities and where the heat transfer means is disposed on the surface of the heat generating component.

A cooling system having one or more heat transfer units with a housing thermally coupled to one or more heat generating components, one more cavities in the housing with a coolant flowing there through for absorbing heat from the heat generating components and a heat transfer means of crystalline carbon for transfer heat from the heat generating components to the cavities and where the heat transfer means forms a surface of the housing thermally coupled to the heat generating components.

A heat spreader for spreading concentrations of heat from hot spots of heat generating components comprised of crystalline carbon.

A system having one or more processors and having a cooling system comprising one or more heat transfer units with a housing thermally coupled to one or more heat generating components, one more cavities in the housing with a coolant flowing there through for absorbing heat from the heat generating components and a heat transfer means of crystalline carbon for transfer heat from the heat generating components to the cavities.

### BRIEF DESCRIPTION OF THE DRAWINGS

FIG. 1A is a top view of the contact surface of the heat transfer unit.

FIG. 1B is a 3-dimensional side-view of the housing of heat transfer unit less the contact surface.

FIG. 2A is a top view of a heat generating component with micro heat spreaders disposed thereon.

FIG. 2B is a 3-dimensional side-view of the housing of heat transfer unit with a partially open contact surface.

FIG. 3 is a system depiction of a cooling system incorporating the heat transfer unit.

### DETAILED DESCRIPTION

While the making and using of various embodiments of the present invention are discussed in detail below, it should be appreciated that the present invention provides many applicable inventive concepts, which can be embodied in a wide variety of specific contexts. The specific embodiments discussed herein are merely illustrative of specific ways to make and use the invention and do not limit the scope of the invention

It should be understood that the principles and applications disclosed herein can be applied in a wide range of data processing systems, telecommunication systems and other systems. In the present invention, heat produced by a heat generating component such as a microprocessor in a data processing system is transfer to a coolant in a heat transfer unit and dissipated in the cooling system. Liquid cooling solves performance and reliability problems associated with heating of various heat generating components in electronic systems.

The present invention may be utilized in a number of computing, communications, and personal convenience applications. For example, the present invention could be implemented in a variety of servers, workstations, exchanges, networks, controllers, digital switches, routers, personal computers which are portable or stationary, cell phones, and personal digital assistants (PDAs) and many others

The present invention is equally applicable to a number of heat-generating components (e.g., central processing units, optical devices, data storage devices, digital signal processors or any component that generates significant heat in operation) within such systems. Furthermore, the dissipation of heat in this cooling system may be accomplished in any number of ways by a heat exchange unit of various designs, but which are note discussed in detail in this application. The present invention may even be combined with a heat exchanger as part of a single unit to constitute the entire cooling system.

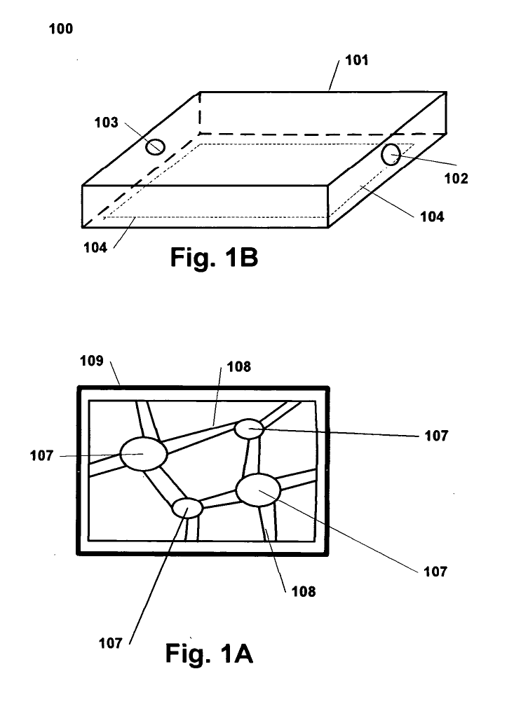

Referring now to FIGS. 1A and 1B, a heat transfer unit 100 embodying the present invention is depicted. In FIG. 1A, a top view of a contact surface 109 is depicted with a plurality of small areas of heat conducting material or micro heat spreaders 107 disposed so that when coupled to a heat generating component such as a microprocessor, they will be in direct thermal contact with known “hot spots” of the heat generating component. The micro heat spreaders 107 may be connected to the contact surface 109 to be held in the correct disposition with respect to the “hot spots” by connectors 108. It will be appreciated that any number of ways to connect the micro heat spreaders to the contact surface 109 may be employed. It will be further appreciated that the term small as used herein is used in the context of comparing the surface area of the micro heat spreader 107 to the surface area of the heat generating component. Although the surface area of the micro heat spreader 107 will vary depending on the particular application, it will in most cases be substantially less than ten per cent of the surface area of the heat generating component.

The micro heat spreaders 107 may be comprised of any number of materials and may be of different shapes. For example, the micro heat spreaders may be rectangular, circular, USCL, or of a specific pattern to match the “hot spot” of the heat generating component. The micro heat spreaders 107 may have ripples or other devices to create non-laminar flow of a coolant or they may be disposed with fins, holes, ridges and other configurations or perform additional cooling functions and/or to direct the coolant flow in a given or desired way. Moreover, the micro heat spreaders 107 may be of a uniform size or of different sizes. In FIG. 1A, the micro heat spreaders 107 are circular and made of thin pieces of copper. A material, such as copper or crystalline carbon, with superior heat transfer capabilities is preferred. Also in FIG. 1A, the micro heat spreaders 107 are of non-uniform size reflecting that, in many cases, the “hot spots” of the heat generating component such as a microprocessor vary in intensity.

The connectors 108 also may be of a variety of shapes, sizes and materials. The principal function of the connectors 108 is to correctly dispose the micro heat spreaders 107 with respect to the “hot spots”. In FIG. 1A, a series of thin, narrow copper strips is depicted for the connectors 108, connecting the micro heat spreaders 107 to the frame of the contact surface 109. It is preferable to make these connectors 108 as thin and as narrow as practical to minimize thermal resistance and maximize the surface area of the heat generating component that will come in direct contact with the coolant flowing through the heat transfer unit 100. It is preferable also, but not required, to have the connectors be of the same material and the same thickness as the small areas. It will again be appreciated that any number of ways be employed within the purview of the present invention to connect the micro heat spreaders 107 to the contact surface 109. Finally, the connectors 109 may have ripples or other devices to create non-laminar flow of a coolant or they may be disposed with fins, holes, ridges and other configurations or perform additional cooling functions and/or to direct the coolant flow in a given or desired way.

The surface contact 109 to which the connectors 108 and micro spreaders 107 are connected serves as a frame to keep the assembly properly aligned and for a connection point to both the housing 101 of heat transfer unit 100. This contact surface may be affixed to housing 101 by means of welding, thermal paste and other means as long as sealed unit is created to prevent leaks or spills of the coolant.

The contact surface 109 after assembly with the housing 105 may also be coupled to the heat generating component by means of a thermal paste or other means. The micro heat spreaders 107 should be thermally coupled to the heat generating component “hot spots” by means of a good thermal paste.

For ease of fabrication, the contact surface 109, the connectors 108 and the micro heat spreaders 107 may be constructed out of a single piece of material, such a copper, by stamping with a press and dye in one cost-effective step.

The contact surface 109 is coupled to housing 101 in FIG. 1B to form the heat transfer unit 100. When this assembly is coupled to one or more heat generating components, a sealed cavity is formed for coolant flow there through. A flange area 104 of the housing 101 is shown for connecting the contact surface 109 to the housing 101. It will be understood however, that any number of methods may be employed to couple the contact surface 102 to the housing 101 and remain within the purview of the present invention.

The housing 101 may be fabricated from a variety of materials with a variety of thicknesses. It may also have any number of shapes so long as it is compatible with the contact surface 109 and the heat generating components to which it will be coupled. It will be understood that, alternatively, the housing 101 may have a solid, sealed surface creating a self-contained cavity for the coolant which is then coupled to the contact surface 109 for indirect contact of the coolant to the micro heat spreaders 107 and the surfaces of the heat generating components.

The housing 101 may also have clip posts or the like (not shown) extending from the exterior surfaces thereof so that the heat transfer unit may be further secured to the heat generating components in the electronic system by clips, for example, extending from a motherboard to which the heat generating components are attached.

The housing 101 also includes an inlet 102 and an outlet 103. The inlet 102 receives cooled coolant from a heat exchanger (not shown) for directing the coolant through the cavity of the housing 101. The outlet 103 receives heated coolant from the cavity of the housing 101 and directs it back to the heat exchanger for cooling and to repeat the cycle. The exchanger receives heated coolant from the heat transfer unit 100, dissipates heat from the coolant, and returns cooled coolant to the heat transfer unit 100.

As cooled coolant enters the cavity of the housing 101 through inlet 102, it is directed across the contact surface 101 coming in direct contact with the micro heat spreaders 107 and the surface of the heat generating component. Heat from the heat generating components is transferred from the micro heat spreaders and the heat generating component to the coolant flowing there over. Then coolant becomes heated and flows on to the outlet 103 where it is directed to a heat exchanger for cooling.

By employing the micro heat spreaders 107 the heat from “hot spots” is spread somewhat providing the coolant with more surface area to absorb heat from. Although some thermal resistance is added by use of the micro heat spreaders, the resulting efficiencies obtained spreading these hotter areas somewhat yields increases in cooling efficiencies more than offsetting the increase in thermal resistance by providing the coolant with more area to absorb the greater heat from. For the remainder of the surface of the heat generating component, direct contact with the coolant is achieved eliminating the thermal resistance of both a surface area of the housing 101 and the large thermal spreaders currently used by many manufacturers.

Whenever possible, it is desirable to orient the heat transfer unit 100 so that the inlet 102 is situated below the outlet 103. This orientation allows the cooling system to take advantage of convective circulation of the coolant since heated coolant will naturally rise and cooled coolant will naturally drop. In this manner, the thermodynamics of the coolant can assist forced circulation, by a pump for example, and provide additional cooling of the heat generating components even after power is shut down to the electronic system.

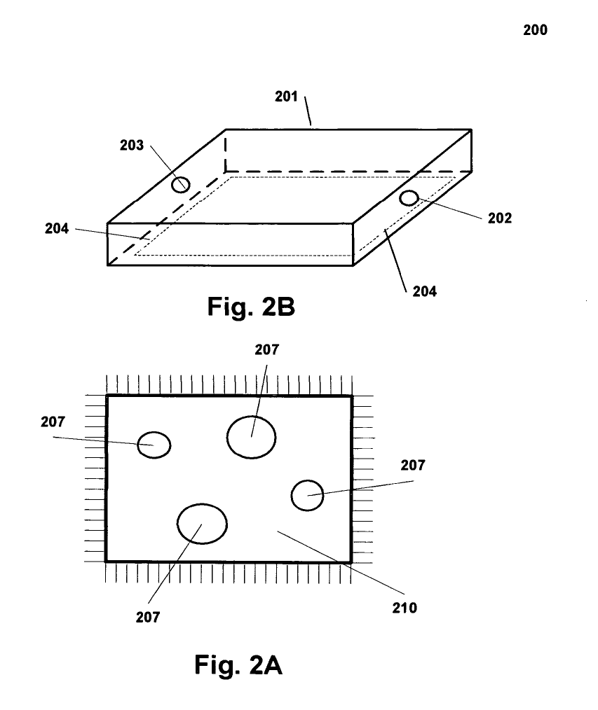

FIGS. 2A and 2B depict another embodiment of the present invention. FIG. 2A is top view of a heat generating component 210 such as a microprocessor with micro heat spreaders 207 thermally coupled thereto at the point of known “hot spots” by means of a thermal paste or other means. In FIG. 2A, the contact surface 109 and connectors 108 of FIG. 1A are eliminated. Instead, the micro heat spreaders 207 are assembled to the heat generating component 210 as part of the manufacturing process for the heat generating component and usually at or near the end the that process. The micro heat spreaders may also have ripples or other devices to create non-laminar flow of the coolant holes, fins or other devices or shapes or to perform additional cooling functions and/or direct the flow of the coolant in a desired manner. It will be appreciated that the micro heat spreaders 207 may embedded in the packaging of the heat generating component 210 or even in the substrate thereof.

FIG. 2B depicts a housing 201 for the heat transfer unit 200.The housing 201 is identical to that of housing 101 in FIG. 1 B. It will be appreciated, however, that housing 201 may be of any number of shapes and sizes and materials. When the housing 201 is coupled to the heat generating component 210, a sealed cavity is formed for the flow of coolant from the inlet 202 through to and out of the outlet 203. Alternatively, the housing 201 may have a thin, solid surface which forms a self-contained cavity within the housing 201 and which is thermally coupled to the heat generating component 210 with the micro heat spreaders 207 coupled thereto or embedded therein for creating indirect contact of the coolant with the micro heat spreaders 207 and the heat generating component 210.

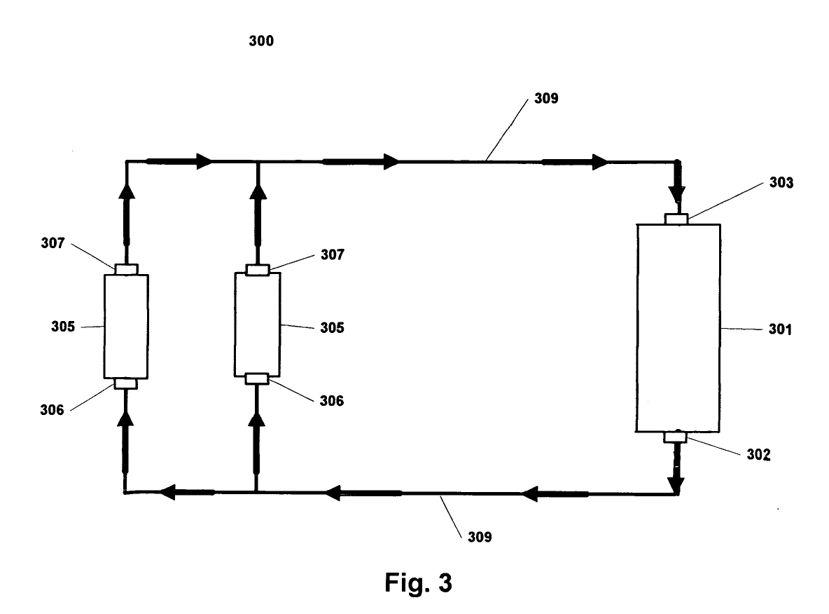

FIG. 3 represents a schematic diagram of a complete cooling system 300 with the heat transfer unit of the present invention. Heat transfer units 305 may be any one of the embodiments of the present invention or a combination of embodiments of the heat transfer units of the present invention and other heat transfer units. Each heat transfer unit 305 has an inlet 306 and an outlet 307. Heat exchanger 301 has an inlet 303 and an outlet 302 and is coupled to the heat transfer units 305 by means of a coolant transport system 309, such as conduits, for example. It will be understood that any number and type of heat exchanger units may be employed with the heat transfer units of the present invention including heat exchanger units with and without reservoirs, with or without a pump, and with and without fans or other air flow devices.

The heat exchanger 301 receives heated coolant from the heat transfer units 305 at its inlet 303. The heat exchanger then dissipates heat from the coolant, creating cooled coolant which is directed to the outlet 302 and on to the inlets 306 of the heat transfer units 305 through the transport system 309 as shown by the directional arrows. The heat transfer units 305 absorb heat from the heat generating components of the electronic system into the coolant, creating heated coolant and directs the heated coolant back to the heat exchanger 301, through the outlets 307 and the coolant transport system 309.

Any number of coolants, liquid or gas, may be used with the present invention such as, for example, a propylene glycol based coolant.

In FIG. 3, the inlets 306 of the heat transfer units are shown disposed below the outlets 307. Similarly, the inlet 303 of the heat exchanger 301 is shown above the outlet 302. Disposition of inlets and outlets in this manner, when possible, maximizes convective circulation of the coolant through the system to enhance the forced circulation of the coolant during normal operation with power and to provide cooling after power shut down to the electronic system.

When coupling any heat transfer unit such as the present invention, other liquid cooling heat transfer units, heat sinks or heat pipes, it is highly desirable to use a thermal compound with high thermal transfer capability and hence low thermal resistance. It is desirable to allow as much heat as possible from the heat generating components be transferred into heat transfer unit and eventually dissipated. This allows for greater thermal cooling of the heat generating component.

With regard to thermally coupling components in general, heat transfer units, and heat transfer units described above, particularly, with the micro heat spreaders 107 or 207, a superior thermal paste can improve performance significantly. A thermal paste comprising finely powdered crystalline carbon can be utilized. The crystalline carbon has extremely superior heat transfer characteristics. A substance such as silicone grease is also added to the finely powdered crystalline carbon for providing a paste-like quality to the compound and insuring a more uniform thermal connection between the components. For certain applications, an adhesive substance may be added to the compound to provide adhesive quality to the paste for securing or helping to secure the components together. The type and amount of grease and/or adhesive added to the finely powdered crystalline carbon depend on the characteristics, size and weight of the components and, in particular, the heat transfer unit. For smaller, lighter-weight heat transfer units and, most particularly, the micro heat spreaders 107 or 207, a very small proportion of the compound need be grease and/or adhesive, thereby maintaining the high heat transfer characteristics of the crystalline carbon.

Alternatively, crystalline carbon may be used in other ways within the purview of the present invention for transferring and/or spreading the heat from the hot spots of the heat generating components. For example, a solid piece of crystalline carbon may be used as the contact surface for a heat transfer unit replacing contact surface 109 in FIG. 1A. A solid piece of crystalline carbon may also be used as a heat spreader replacing the areas of heat conducting material 207 in FIG. 2A. The crystalline carbon may also be embedded in the packaging or the substrate of the heat generating component in single, stacked, and multiple die or wafers to spread the heat form the hot spots, or transfer heat to the heat transfer unit or both. In such cases, a heat transfer unit with a solid contact surface or an open or partially open contact surface (allowing a coolant to come into direct contact with the heat generating component) may be used to absorb heat from the heat generating component for dissipation by the cooling system.

Thus, the present invention has been described herein with reference to particular embodiments for particular applications. Those having ordinary skill in the art and access to the present teachings will recognize additional modifications, applications, and embodiments within the scope thereof.

It is, therefore, intended by the appended claims to cover any and all such applications, modifications, and embodiments within the scope of the present invention.

1. A cooling system for cooling heat-generating components in an electronic system having one or more heat transfer units, one of the one or more heat transfer units comprising:
a housing having a cavity for a coolant to flow there through and coupled to one or more heat-generating components;
one or more small areas of heat conducting material physically disposed so as to be thermally coupled to known hot spots of the one or more heat-generating components; and
wherein the coolant absorbs heat from the one or more small areas of heat conducting material and the one or more heat-generating components.

2. The cooling system of claim 1 wherein the housing has at least one surface open or partially open and such surface is thermally coupled to the one or more heat-generating components and forming the cavity there with such that the coolant comes in direct contact with the small areas of heat conducting material and at least one surface of the heat-generating components.

3. The cooling system as set forth in claim 2 further comprising means for connecting the one or more small areas of heat conducting material to the housing along the open or partially open surface of such housing.

4. The cooling system as set forth in claim 1 wherein the one or more small areas of heat conducting materials are coupled to or within at least one heat-generating component before coupling the heat transfer unit housing to the one or more heat-generating components.

5. The cooling system of claim 4 wherein the housing has at least one surface open or partially open surface and such surface is coupled to the one or more heat-generating components and forming the cavity therewith such that the coolant comes in direct contact with at least one surface of the heat-generating components.

6. The cooling system as set forth in claim 1 further comprising;
a housing inlet for receiving cooled coolant and directing the cooled coolant to the cavity;
a housing outlet for receiving heated coolant from the cavity and directing the heated coolant out of the housing; and
wherein the inlet is disposed below the outlet to enhance convective circulation of the coolant.

7. The cooling system as set forth in claim 1 further comprising;
a heat exchange unit for receiving heated coolant from the heat transfer units, cooling the coolant by dissipating heat from the coolant and generating cooled coolant for transporting to the heat transfer units; and
means for transporting heated coolant from the heat transfer units to the heat exchange unit and transporting cooled coolant from the heat exchange unit to the heat transfer units.

8. The cooling system as set forth in claim 1 wherein the small areas of heat conducting material are comprised of crystalline carbon.

9. An optical device having the cooling system of claim 1.

10. A system having one or more processors and having the cooling system of claim 1.

11. A method of cooling heat-generating components in an electronic system having one or more heat transfer units, each heat transfer unit thermally coupled to at least one surface of one or more heat-generating components and wherein at least one heat generating component has one or more small areas of heat conducting material thermally coupled to known hot spots of the heat generating component, the method comprising the steps of:
receiving cooled coolant at the heat transfer unit;
transporting the cooled coolant through a cavity in the heat transfer units;
removing heat from the heat-generating components by transferring such heat from the small areas of heat conducting materials and from the surfaces of the heat-generating components into the coolant, and
transporting the heated coolant from the cavity.

12. A method of cooling as set forth in claim 11 wherein at least one heat transfer unit has an open or partially open surface coupled to one or more heat-generating components such that the coolant comes in direct contact with the small areas of heat conducting material and the heat generating component.

13. A method of cooling as set forth in claim 11 wherein the heat transfer unit has an inlet for receiving cooled coolant and an outlet for receiving heated coolant from the cavity, the method further comprising the step of
positioning the inlet below the outlet to enhance convective circulation.

14. A method of cooling as set forth in claim 11, the method further comprising the steps of:
transporting the heated coolant from the heat transfer units to a heat exchange unit;
cooling the heated coolant in the heat exchange unit by dissipating heat from the coolant and creating cooled coolant; and
transporting the cooled coolant from the heat exchange unit to the heat transfer units.

15. A compound for thermally coupling components having finely powdered crystalline carbon.

16. The compound as set forth in claim 15 further comprising a substance for providing a paste-like texture to the compound for enhancing a uniform thermal coupling of the components.

17. The compound as set forth in claim 16 further comprising a substance for providing adhesive quality to the compound for securing the components.

18. The compound as set forth in claim 16 for coupling one or more heat-generating components to one more heat transfer units.

19. A electronic system having one or more processors thermally coupled to another component with the compound of claim 15.

20. An optical device having components thermally coupled together with the compound of claim 15.

21. A cooling system for cooling heat-generating components in a system and having one or more heat transfer units, the heat transfer units comprising:
a housing coupled to one or more heat-generating components;
one or more cavities disposed in the housing and thermally coupled to the heat-generating components wherein a coolant flowing through the cavities absorbs heat from the heat-generating components creating heated coolant; and
a heat transfer means for transferring heat from the heat-generating components to the cavities and wherein the heat transfer means is comprised of crystalline carbon.

22. The cooling system as set forth in claim 21 wherein the heat transfer means is embedded in the packaging of the heat-generating components.

23. The cooling system as set forth in claim 21 wherein the heat transfer means is embedded in the substrate of the heat-generating components.

24. The cooling system as set forth in claim 21 wherein the heat transfer means is disposed on the surface of the heat-generating components.

25. The cooling system as set forth in claim 21 wherein the heat transfer means is a surface of the housing thermally coupled to the heat-generating components.

26. A system having one or more processors and having the cooling system of claim 21.

27. A heat spreader for spreading concentrations of heat from hot spots of heat generating components comprising crystalline carbon.
